(19) United States
(12) Patent Application Publication
(10) Pub. No.: US 2024/0266097 A1
(43) Pub. Date: Aug. 8, 2024

(54) ELECTRONIC COMPONENT

(71) Applicant: TDK Corporation, Tokyo (JP)

(72) Inventors: Xuran GUO, Tokyo (JP); Youichi Kazuta, Tokyo (JP); Kazuya Tobita, Tokyo (JP); Yuto Shiga, Tokyo (JP); Yuichi Takubo, Tokyo (JP); So Kobayashi, Tokyo (JP); Hiroto Komatsu, Tokyo (JP); Toru Yaginuma, Tokyo (JP)

(73) Assignee: TDK Corporation, Tokyo (JP)

(21) Appl. No.: 18/426,523

(22) Filed: Jan. 30, 2024

(30) Foreign Application Priority Data
Feb. 2, 2023 (JP) 2023-014767

(51) Int. Cl. H01F 5/04

(52) U.S. Cl. CPC H01F 5/04

(57) ABSTRACT

The electronic component includes an element body, a first external electrode, and a second external electrode. The first external electrode and the second external electrode are disposed on a principal surface and are separated from each other in a first direction. The first external electrode includes a first region and a second region. The first region includes an end edge that opposes the second external electrode in the first direction and is located inside the element body. The second region is continuous with the first region and is exposed from the principal surface. The second external electrode includes a third region and a fourth region. The third region includes an edge that opposes the first region in the first direction and is located inside the element body. The fourth region is continuous with the third region and is exposed from the principal surface.

### CROSS-REFERENCE TO RELATED APPLICATIONS

This application is based upon and claims the benefit of priority from Japanese Patent Application No. 2023-014767, filed on Feb. 2, 2023. The entire contents of which are incorporated herein by reference.

### BACKGROUND

### Field

The present disclosure relates to an electronic component.

### Description of the Related Art

Known electronic components include an element body and a pair of external electrodes disposed on the element body and separated from each other (for example, refer to Japanese Unexamined Patent Publication No. 2018-113299).

### SUMMARY

In the above-described electronic component, the pair of external electrodes may be short-circuited for the following reason.

A plated layer may be formed on the external electrode to improve mountability of the electronic component. When the plated layer is formed on the external electrode, the plated layer may grow from the external electrode on the element body. For example, when the plated layer grows on the element body from each of the pair of external electrodes, the interval between the pair of external electrodes is substantially narrowed. In this case, the pair of external electrodes may be short-circuited. A phenomenon in which the plated layer grows on the element body is called plating elongation.

An object of an aspect of the present disclosure is to prepare an electronic component that suppresses a short circuit between a pair of external electrodes.

An electronic component according to one aspect of the present disclosure includes an element body, a first external electrode, and a second external electrode. The element body includes a principal surface, a pair of first side surfaces opposing each other in a first direction and adjacent to the principal surface, and a pair of second side surfaces opposing each other in a second direction intersecting with the first direction and adjacent to the principal surface. The first external electrode and the second external electrode are disposed on the principal surface and are separated from each other in the first direction. The first external electrode includes a first region and a second region. The first region includes an end edge that opposes the second external electrode in the first direction and is located inside the element body. The second region is continuous with the first region and is exposed from the principal surface. The second external electrode includes a third region and a fourth region. The third region includes an edge that opposes the first region in the first direction and is located inside the element body. The fourth region is continuous with the third region and is exposed from the principal surface.

In the one aspect, the edges included in each of the first region and the third region oppose each other in the first direction. Each end edge is located in the element body. Therefore, even in a case where the plated layer is formed on each of the first external electrode and the second external electrode, the plating elongation tends not to occur from each end edge. A gap between a first external electrode and a second external electrode is prevented from narrowing. As a result, in the one aspect, a short circuit between the first external electrode and the second external electrode is suppressed.

An end edge included in each of the first region and the third region is located in the element body. Therefore, the one aspect improves the connection strength between the element body and the first external electrode and the second external electrode.

In the one aspect, each of the first external electrode and the second external electrode may entirely overlap an imaginary region when viewed in a direction orthogonal to the principal surface. The imaginary region may be defined by a pair of first imaginary planes each including a corresponding first side surface of the pair of first side surfaces and a pair of second imaginary planes each including a corresponding second side surface the pair of second side surfaces.

In the configuration in which each of the first external electrode and the second external electrode entirely overlaps the imaginary region, the region where the solder fillet is formed when the electronic component is solder-mounted on the electronic device tends not to increase. Therefore, the present configuration can improve the mounting density of electronic components on an electronic device. The electronic device includes, for example, a circuit board or an electronic component.

In the one aspect, each of the second region and the fourth region may include an outer edge overlapping a corresponding imaginary plane of a pair of imaginary planes when viewed in a direction orthogonal to the principal surface. The pair of imaginary planes each may include a corresponding first side surface of the pair of first side surfaces.

In the configuration in which each of the second region and the fourth region includes the outer edge, the length of each of the second region and the fourth region in the first direction increases. Accordingly, this configuration may increase the area of each of the second region and the fourth region. As a result, this configuration can improve the mounting strength of the electronic component.

In the one aspect, each of the second region and the fourth region may include a pair of outer edges each overlapping a corresponding imaginary plane of a pair of imaginary planes when viewed in a direction orthogonal to the principal surface. The pair of imaginary planes each may include a corresponding second side surface of the pair of second side surfaces.

In the configuration in which each of the second region and the fourth region includes the pair of outer edges, the length of each of the second region and the fourth region in the second direction increases. Therefore, this configuration can increase the area of each of the first external electrode and the second external electrode. As a result, this configuration can improve the mounting strength of the electronic component.

In the one aspect, each of the first region and the third region may be separated from a pair of imaginary planes when viewed in a direction orthogonal to the principal surface. The pair of imaginary planes each may include a corresponding second side surface of the pair of second side surfaces.

In the configuration in which each of the first region and the third region is separated from the pair of imaginary planes, the end edge included in each of the first region and the third region tends to be reliably positioned in the element body. Therefore, the present configuration reliably suppresses a short circuit between the first external electrode and the second external electrode.

In the one aspect, a distance in the second direction between each of the pair of second imaginary planes and the first region may be larger than a length of the first region in the first direction. A distance in the second direction between each of the pair of second imaginary planes and the third region may be larger than a length of the third region in the first direction.

In the configuration in which the distance in the second direction between each of the pair of second imaginary planes and the first region is larger than the length of the first region in the first direction, the first region is reliably separated from each of the pair of second imaginary planes. In the configuration in which the distance in the second direction between each of the pair of second imaginary planes and the third region is larger than the length of the third region in the first direction, the third region is reliably separated from each of the pair of second imaginary planes. Therefore, the end edge included in each of the first region and the third region can be more reliably positioned in the element body. As a result, these configurations more reliably suppress a short circuit between the first external electrode and the second external electrode.

In the one aspect, the ratio of the area of the first region to the area of the first external electrode and the ratio of the area of the third region to the area of the second external electrode may be a range from 0.1 to 0.2.

In the configuration in which each of the ratios is a range from 0.1 to 0.2, the connection strength between the first external electrode and the second external electrode can be improved, and each area of the second region and the fourth region can be secured. Therefore, this configuration can secure the mounting strength of the electronic component.

The present disclosure will become more fully understood from the detailed description given hereinafter and the accompanying drawings which are given by way of illustration only, and thus are not to be considered as limiting the present disclosure.

Further scope of applicability of the present disclosure will become apparent from the detailed description given hereinafter. However, it should be understood that the detailed description and specific examples, while indicating examples of the disclosure, are given by way of illustration only, since various changes and modifications within the spirit and scope of the disclosure will become apparent to those skilled in the art from this detailed description.

### BRIEF DESCRIPTION OF THE DRAWINGS

FIG. 1 is a perspective view illustrating an electronic component according to an example;

FIG. 2 is a side view illustrating the electronic component according to the present example;

FIG. 3 is a bottom view illustrating the electronic component according to the present example;

FIG. 4 is a side view illustrating the electronic component according to the present example;

FIG. 5 is a side view illustrating the electronic component according to the present example;

FIG. 6 is a perspective view illustrating the electronic component according to the present example;

FIG. 7 is a perspective view illustrating an electronic component according to the present example; and

FIG. 8 is an exploded perspective view illustrating the electronic component according to the present example.

### DETAILED DESCRIPTION

Hereinafter, examples of the present disclosure will be described in detail with reference to the accompanying drawings. In the following description, the same elements or elements having the same functions are denoted with the same reference numerals and overlapped explanation is omitted.

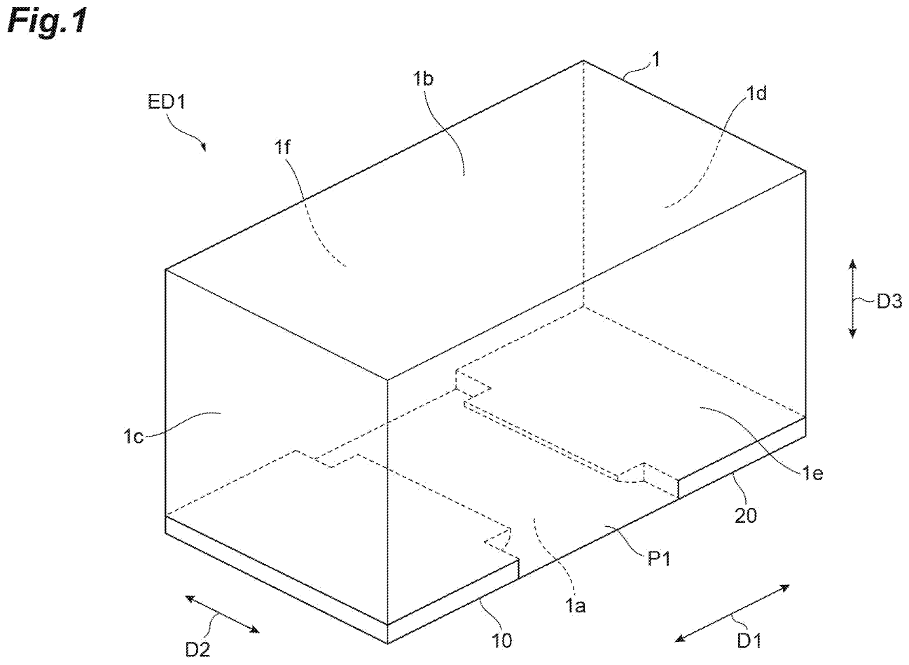

In the present specification, a configuration and a producing method of an electronic component ED1 will be described with reference to FIGS. 1 to 8. The electronic component ED1 includes, for example, a multilayer inductor. For example, the electronic component ED1 is formed of the multilayer inductor.

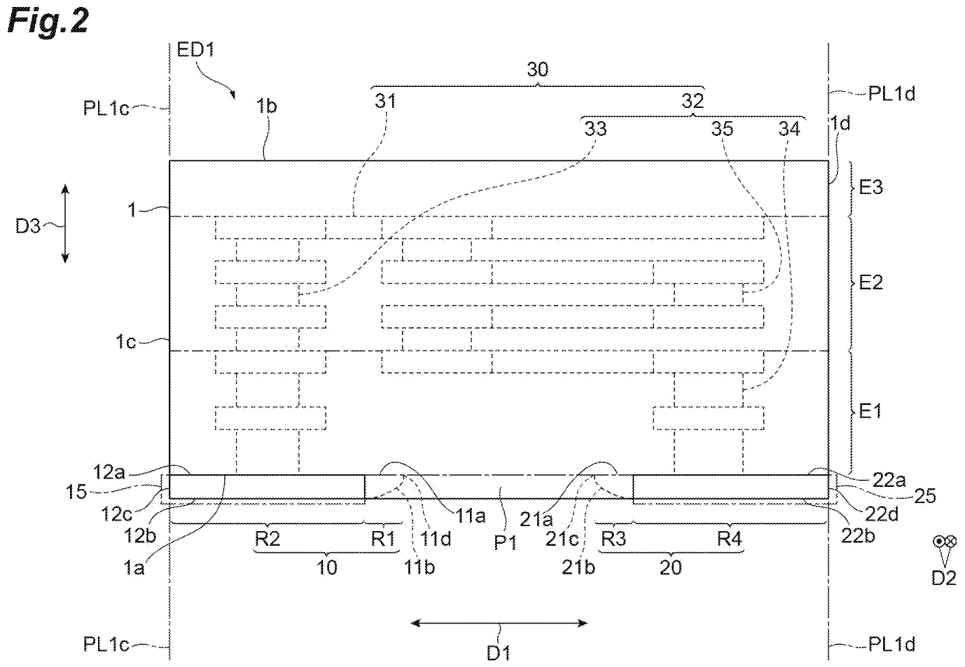

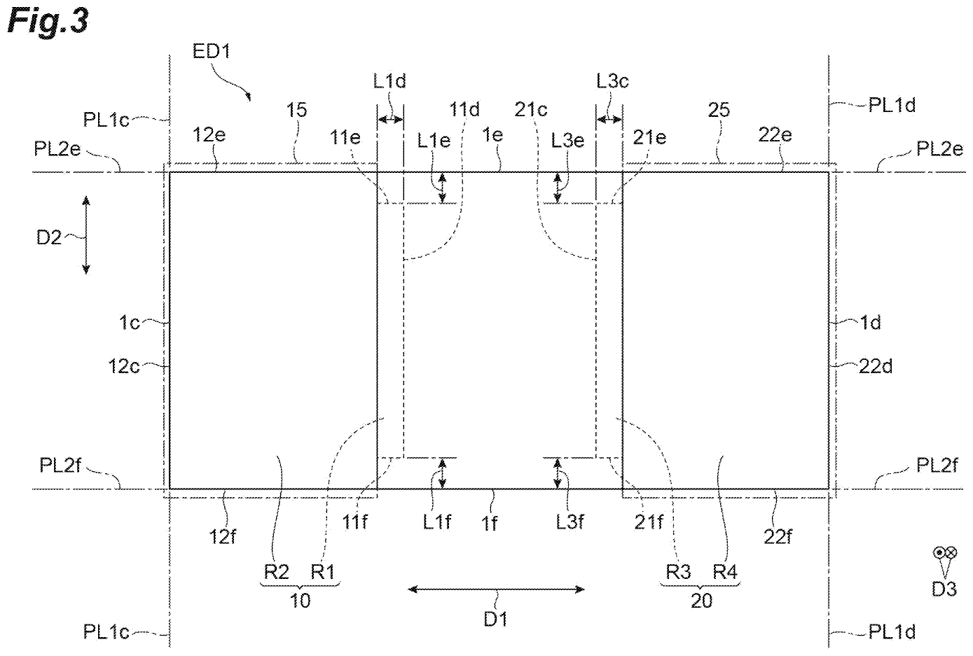

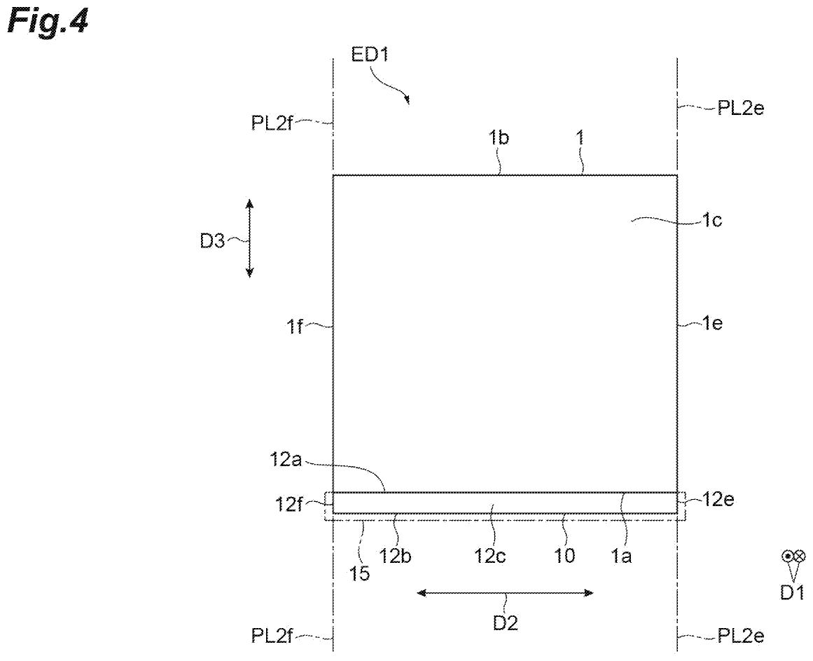

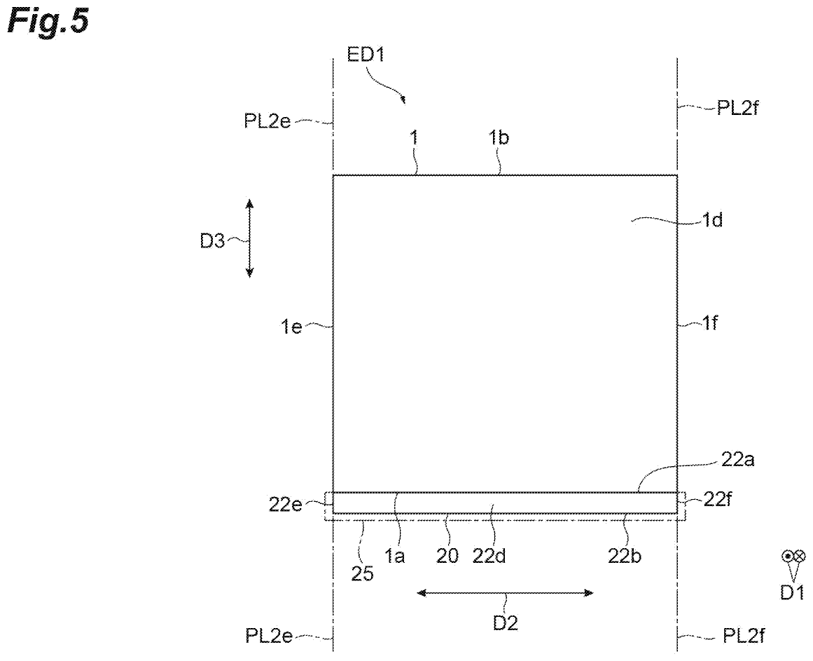

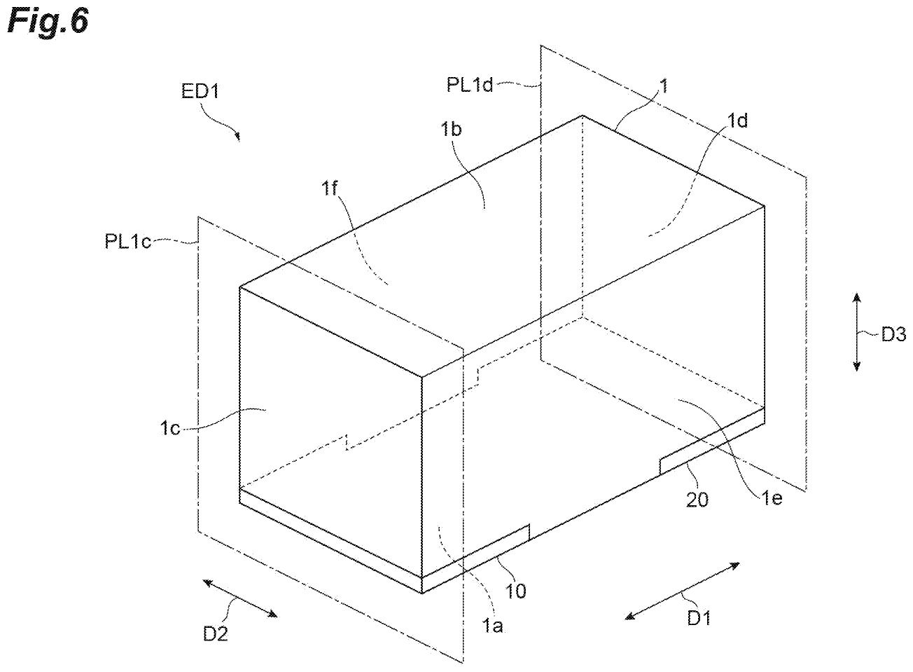

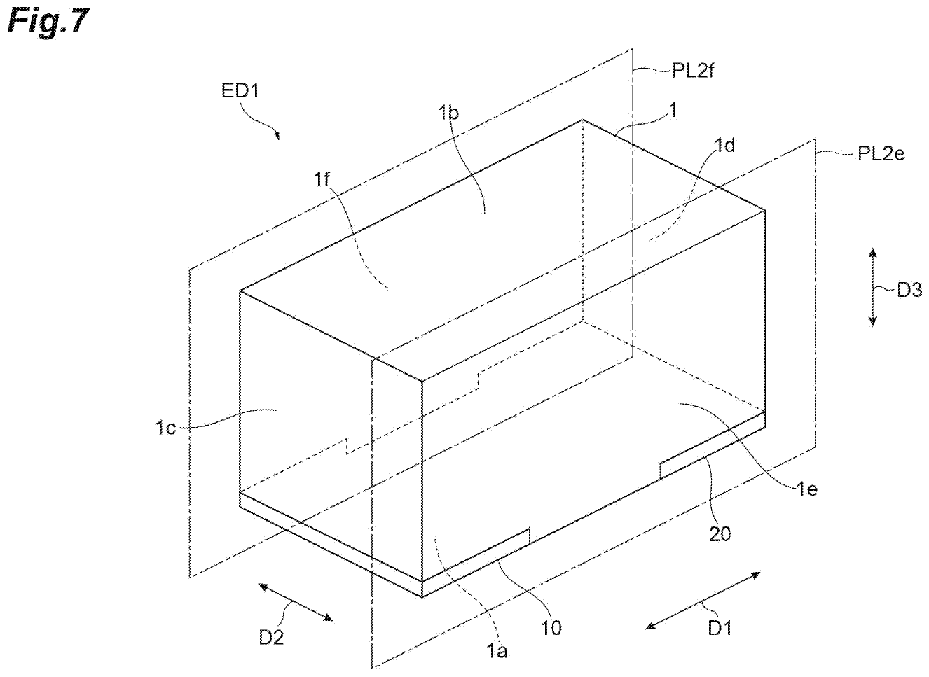

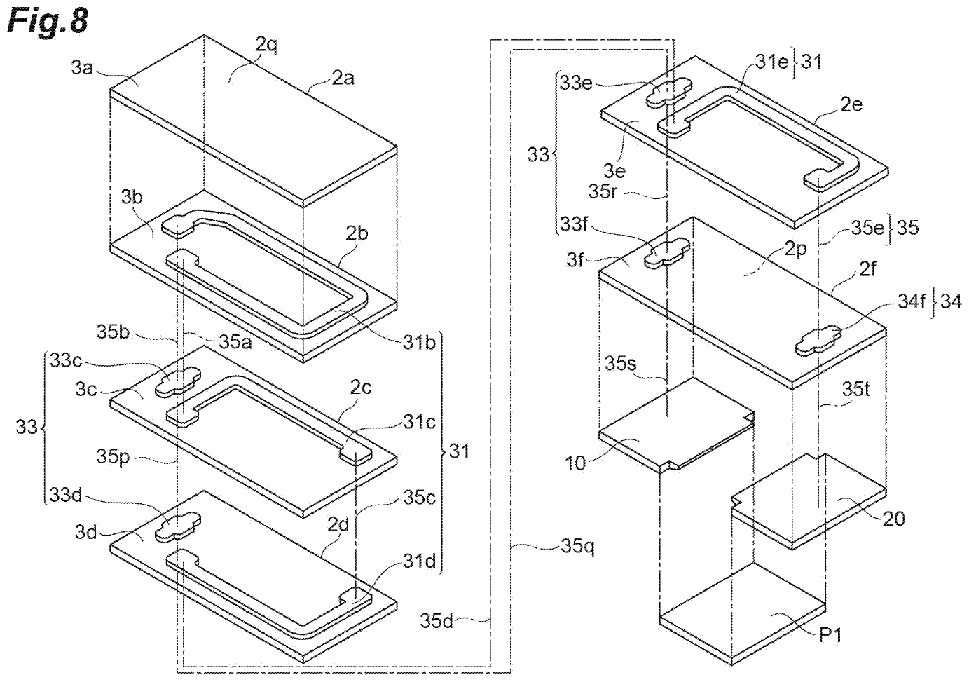

FIG. 1 is a perspective view illustrating an electronic component according to the present example. FIG. 2 is a side view illustrating the electronic component according to the present example. FIG. 3 is a bottom view illustrating the electronic component according to the present example. FIGS. 4 and 5 are side views illustrating the electronic component according to the present example. FIGS. 6 and 7 are perspective views illustrating the electronic component according to the present example. FIG. 8 is an exploded perspective view illustrating the electronic component according to the present example.

The configuration of the electronic component ED1 will be described with reference to FIGS. 1 to 8. The electronic component ED1 includes an element body 1, a plurality of external electrodes 10 and 20, and an internal conductor 30. The internal conductor 30 is electrically connected to the external electrodes 10 and 20. For example, the electronic component ED1 includes a pair of external electrodes 10 and 20.

The element body 1 has, for example, a rectangular parallelepiped shape. The element body 1 includes a pair of principal surfaces 1a and 1b opposing each other, a pair of side surfaces 1c and 1d opposing each other, and a pair of side surfaces 1e and 1f opposing each other. The outer surfaces of the element body 1 include principal surfaces 1a and 1b and four side surfaces 1c, 1d, 1e, and 1f. Each of the principal surfaces 1a and 1b and the four side surfaces 1c, 1d, 1e, and 1f has, for example, a rectangular shape. For example, when the side surfaces 1c and 1d include a pair of first side surfaces, the side surfaces 1e and 1f include a pair of second side surfaces.

In the present example, the principal surface 1a includes a mounting surface. When the electronic component ED1 is mounted on an electronic device, the principal surface 1a opposes the electronic device. The electronic device includes a circuit board or an electronic component. The principal surface 1b may include the mounting surface. The “rectangular parallelepiped shape” in the present specification includes a rectangular parallelepiped shape in which corner portions and ridge portions are chamfered or a rectangular parallelepiped shape in which corner portions and ridge portions are rounded. The “rectangular shape” in the present specification includes a shape in which each corner is chamfered or a shape in which each corner is rounded.

The side surfaces 1c and 1d oppose each other in the first direction D1. The side surfaces 1e and 1f oppose each other in the second direction D2. The principal surfaces 1a and 1b oppose each other in the third direction D3. The first direction D1 intersects the second direction D2 and intersects the third direction D3. In the present example, the first direction D1 is orthogonal to the second direction D2 and orthogonal to the third direction D3. The second direction D2 intersects the third direction D3. In the present example, the second direction D2 is orthogonal to the third direction D3, and the third direction D3 is orthogonal to the principal surface 1a.

Each of the principal surfaces 1a and 1b extends in the first direction D1 to couple the side surfaces 1c and 1d. Each of the principal surfaces 1a and 1b extends in the second direction D2 to couple the side surfaces 1e and 1f. Each of the side surfaces 1c and 1d extends in the third direction D3 to couple the principal surfaces 1a and 1b. Each of the side surfaces 1c and 1d extends in the second direction D2 to couple the side surfaces 1e and 1f. Each of the side surfaces 1e and 1f extends in the third direction D3 to couple the principal surfaces 1a and 1b. Each of the side surfaces 1e and 1f extends in the first direction D1 to couple the side surfaces 1c and 1d. Each of the principal surfaces 1a and 1b is adjacent to four side surfaces 1c, 1d, 1e, and 1f. The side surfaces 1c and 1d are adjacent to the side surfaces 1e and 1f. Each of the principal surfaces 1a and 1b may be indirectly adjacent to each of the four side surfaces 1c, 1d, 1e, and 1f. Each of the side surfaces 1c and 1d may be indirectly adjacent to the side surfaces 1e and 1f.

The element body 1 is, for example, about 0.4 mm long in the first direction D1. The element body 1 is, for example, about 0.2 mm long in the second direction D2. The element body 1 is, for example, about 0.2 mm long in the third direction D3. In the present example, the first direction D1 is the longitudinal direction of the element body 1.

The external electrodes 10 and 20 are disposed on the principal surface 1a. The external electrodes 10 and 20 are separated from each other in the first direction D1. The external electrode 10 is disposed closer to the side surface 1c than the external electrode 20. The external electrode 20 is disposed closer to the side surface 1d than the external electrode 10. For example, when the external electrode 10 includes a first external electrode, the external electrode 20 includes a second external electrode.

The external electrode 10 includes a region R1 and a region R2 continuous with the region R1. The region R1 opposes the external electrode 20 in the first direction D1. The region R1 includes a surface region 11a and a surface region 11b. The surface region 11a is in contact with the element body 1. The surface region 11b opposes the surface region 11a in the third direction D3. The surface region 11b includes an edge 11d. The edge 11d opposes the external electrode 20 in the first direction D1.

The region R2 includes a surface region 12a and a surface region 12b. The surface region 12b opposes the surface region 12a in the third direction D3. The surface region 12a is in contact with the element body 1. The region R2 is exposed from the principal surface 1a. In the present example, the entire region R2 is exposed from the principal surface 1a. For example, when the region R1 includes a first region, the region R2 includes a second region.

The region R1 and the region R2 have, for example, a rectangular shape when viewed in the third direction D3. In the present example, when viewed in the second direction D2, the surface region 11b monotonically approaches the element body 1 as the distance from the surface region 12b increases. The portion including the surface region 11b may have a rectangular shape when viewed in the second direction D2.

The region R1 includes a pair of edges 11e and 11f. The edges 11e and 11f oppose each other in the second direction D2. The edges 11e and 11f define both ends of the region R1 in the second direction D2. The edge 11e is located closer to the side surface 1e than the edge 11f when viewed in the third direction D3. The edge 11f is located closer to the side surface 1f than the edge 11e when viewed in the third direction D3.

The region R2 includes an outer edge 12c and a pair of outer edges 12e and 12f. The outer edge 12c defines one end of the region R2 in the first direction D1. The outer edge 12c is located closer to the side surface 1c than the region R1 when viewed in the third direction D3. The outer edges 12e and 12f define both ends of the region R2 in the second direction D2. The outer edge 12e is located closer to the side surface 1e than the outer edge 12f when viewed in the third direction D3. The outer edge 12f is located closer to the side surface 1f than the outer edge 12e when viewed in the third direction D3.

In the present example, the side surfaces 1c, 1d, 1e, and 1f are included in the imaginary plane. The imaginary planes include, for example, a pair of imaginary planes PL1c and PL1d and a pair of imaginary planes PL2e and PL2f. The imaginary plane PL1c includes the side surface 1c. The imaginary plane PL1d includes the side surface 1d. The imaginary plane PL1c is orthogonal to the principal surface 1a. The imaginary plane PL1d is orthogonal to the principal surface 1a and opposes the imaginary plane PL1c in the first direction D1. The imaginary plane PL2e includes the side surface 1e. The imaginary plane PL2f includes the side surface 1f. The imaginary plane PL2e includes a side surface 1e. The imaginary plane PL2f includes a side surface 1f. The imaginary plane PL2e is orthogonal to the principal surface 1a, and is orthogonal to the imaginary plane PL1c and the imaginary plane PL1d. The imaginary plane PL2f opposes the imaginary plane PL2e in the second direction D2. The imaginary plane PL2f is orthogonal to the principal surface 1a, and orthogonal to the imaginary plane PL1c and the imaginary plane PL1d. For example, when the imaginary planes PL1c and PL1d include a pair of first imaginary planes, the imaginary planes PL2e and PL2f include a pair of second imaginary planes.

When viewed in the third direction D3, an entirety of the external electrode 10 is located in a region defined by the imaginary planes PL1c and PL1d and the imaginary planes PL2e and PL2f. When viewed in the third direction D3, the entirety of the external electrode 10 overlaps a region defined by the imaginary planes PL1c and PL1d and the imaginary planes PL2e and PL2f. The entirety of each of the region R1 and the region R2 is located in a region defined by the imaginary planes PL1c and PL1d and the imaginary planes PL2e and PL2f when viewed in the third direction D3. The entirety of each of the region R1 and the region R2 overlaps with a region defined by the imaginary planes PL1c and PL1d and the imaginary planes PL2e and PL2f when viewed in the third direction D3.

The region R1 is separated from the imaginary planes PL2e and PL2f when viewed in the third direction D3. The edge 11e is separated from the imaginary plane PL2e when viewed in the third direction D3. The edge 11f is separated from the imaginary plane PL2f when viewed in the third direction D3.

In the region R2, the outer edge 12c is located closer to the imaginary plane PL1c than the region R1 when viewed in the third direction D3. In the present example, the outer edge 12c is located in the imaginary plane PL1c when viewed in the third direction D3. The outer edge 12c overlaps the imaginary plane PL1c when viewed in the third direction D3. The outer edge 12e is located in the imaginary plane PL2e when viewed in the third direction D3. The outer edge 12e overlaps the imaginary plane PL2e when viewed in the third direction D3. The outer edge 12f is located in the imaginary plane PL2f when viewed in the third direction D3. The outer edge 12f overlaps the imaginary plane PL2f when viewed in the third direction D3.

In the present example, a distance L1e between the imaginary plane PL2e and the region R1 in the second direction D2 is larger than a length L1d of the region R1 in the first direction D1. The distance L1e is defined by a distance between the imaginary plane PL2e and the edge 11e in the second direction D2. A distance L1f between the imaginary plane PL2f and the region R1 in the second direction D2 is larger than the length L1d of the region R1 in the first direction D1. The distance L1f is defined by a distance between the imaginary plane PL2f and the edge 11f in the second direction D2. The L1d is, for example, 15 to 50 μm. The ratio of the area of the region R1 to an area of the external electrode 10 is, for example, a range from 0.1 to 0.2. The areas of the external electrode 10 are areas of the entire regions including the regions R1 and R2 of the external electrode 10.

The external electrode 20 includes a region R3 and a region R4 continuous with the region R3. The region R3 opposes the region R1 in the first direction D1. The region R3 includes a surface region 21a and a surface region 21b. The surface region 21a is in contact with the element body 1. The surface region 21b opposes the surface region 21a in the third direction D3. The surface region 21b includes an edge 21c. The end edge 21c opposes the external electrode 10 in the first direction D1.

The region R4 includes a surface region 22a and a surface region 22b. The surface region 22b opposes the surface region 22a in the third direction D3. The surface region 22a is in contact with the element body 1. The region R4 is exposed from the principal surface 1a. In the present example, the entire region R4 is exposed from the principal surface 1a. For example, when the region R3 includes a third region, the region R4 includes a fourth region.

The region R3 and the region R4 have, for example, a rectangular shape when viewed in the third direction D3. In the present example, when viewed in the second direction D2, the surface region 21b monotonically approaches the element body 1 as the distance from the surface region 22b increases. The portion including the surface region 21b may have a rectangular shape when viewed in the second direction D2.

The region R3 includes a pair of edges 21e and 21f. The edges 21e and 21f oppose each other in the second direction D2. The edges 21e and 21f define both ends of the region R3 in the second direction D2. The edge 21e is located closer to the side surface 1e than the edge 21f when viewed in the third direction D3. The edge 21f is located closer to the side surface 1f than the edge 21e when viewed in the third direction D3.

The region R4 includes an outer edge 22d and a pair of outer edges 22e and 22f. The outer edge 22d defines one end of the region R4 in the first direction D1. The outer edge 22d is located closer to the side surface 1d than the region R3 when viewed in the third direction D3. The outer edges 22e and 22f define both ends of the region R4 in the second direction D2. The outer edge 22e is located closer to the side surface 1e than the outer edge 22f when viewed in the third direction D3. The outer edge 22f is located closer to the side surface 1f than the outer edge 22e when viewed in the third direction D3.

When viewed in the third direction D3, the entirety of the external electrode 20 is located in a region defined by the imaginary planes PL1c and PL1d and the imaginary planes PL2e and PL2f. When viewed in the third direction D3, the entirety of the external electrode 20 overlaps a region defined by the imaginary planes PL1c and PL1d and the imaginary planes PL2e and PL2f. The entirety of each of the region R3 and the region R4 is located in a region defined by the imaginary planes PL1c and PL1d and the imaginary planes PL2e and PL2f when viewed in the third direction D3. The entirety of each of the region R3 and the region R4 overlaps with a region defined by the imaginary planes PL1c and PL1d and the imaginary planes PL2e and PL2f when viewed in the third direction D3.

The region R3 is separated from the imaginary planes PL2e and PL2f when viewed in the third direction D3. The edge 21e is separated from the imaginary plane PL2e when viewed in the third direction D3. The edge 21f is separated from the imaginary plane PL2f when viewed in the third direction D3.

In the region R4, the outer edge 22d is located closer to the imaginary plane PL1d than the region R3 when viewed in the third direction D3. In the present example, the outer edge 22d is located on the imaginary plane PL1d when viewed in the third direction D3. The outer edge 22d overlaps the imaginary plane PL1d when viewed in the third direction D3. The outer edge 22e is located in the imaginary plane PL2e when viewed in the third direction D3. The outer edge 22e overlaps the imaginary plane PL2e when viewed in the third direction D3. The outer edge 22f is located in the imaginary plane PL2f when viewed in the third direction D3. The outer edge 22f overlaps the imaginary plane PL2f when viewed in the third direction D3.

In the present example, a distance L3e between the imaginary plane PL2e and the region R3 in the second direction D2 is larger than a length L3c of the region R3 in the first direction D1. The distance L3e is defined by a distance between the imaginary plane PL2e and the edge 21e in the second direction D2. A distance L3f between the imaginary plane PL2f and the region R3 in the second direction D2 is larger than the distance L3c of the region R3 in the first direction D1. The distance L3f is defined by a distance between the imaginary plane PL2f and the edge 21f in the second direction D2. The length L3c is, for example, 15 to 50 μm. The ratio of the areas of the region R3 to the areas of the external electrodes 20 is a range from 0.1 to 0.2. The areas of the external electrode 20 are areas of the entire regions including the regions R3 and R4 of the external electrode 20.

The element body 1 includes an element body region E1, an element body region E2, and an element body region E3. The element body region E1 includes the principal surface 1a. The element body region E3 includes the principal surface 1b. The element body region E2 is located between the element body region E1 and the element body region E3 in the third direction D3. The element body region E1 includes a portion P1. The portion P1 is located between the external electrode 10 and the external electrode 20 to be in contact with the external electrodes 10 and 20.

In the region R1, the surface region 11b is covered with the portion P1. The edges 11e and 11f are covered with the portion P1. The region R1 is covered with the element body 1. The region R1 is located in the element body 1. In the present example, the entire region R1 is located within the element body 1. The region R1 is buried in the element body 1. In the present example, the entire region R1 is buried in the element body 1. The surface region 11b and the edges 11e and 11f are buried in the element body 1.

In the region R3, the surface region 21b is covered with the portion P1. The edges 21e and 21f are covered with the portion P1. The region R3 is covered with the element body 1. The region R3 is located in the element body 1. In the present example, the entire region R3 is located within the element body 1. The region R3 is buried in the element body 1. In the present example, the entire region R3 is buried in the element body 1. The surface region 21b and the edges 21e and 21f are buried in the element body 1.

The electronic component ED1 includes a plated layer 15 on the external electrode 10. The plated layer 15 is formed on the external electrode 10 to improve mountability of the electronic component ED1. The plated layer 15 is formed on the region R2 exposed from the principal surface 1a. In the present example, the plated layer 15 is formed on the surface region 12b and the outer edges 12c, 12e, and 12f. The plated layer 15 formed on the outer edge 12c is located outside the element body 1 as compared with the imaginary plane PL1c. The plated layer 15 formed on the outer edge 12e is located outside the element body 1 as compared with the imaginary plane PL2e. The plated layer 15 formed on the outer edge 12f is located outside the element body 1 as compared with the imaginary plane PL2f. The plated layer 15 is not formed in the region R1 located in the element body 1. The plated layer 15 is not formed on the edges 11e and 11f.

The electronic component ED1 includes a plated layer 25 on the external electrode 20. The plated layer 25 is formed on the external electrode 20 to improve mountability of the electronic component ED1. The plated layer 25 is formed on the region R4 exposed from the principal surface 1a. In the present example, the plated layer 25 is formed on the surface region 22b and the outer edges 22d, 22e, and 22f. The plated layer 25 formed on the outer edge 22d is located outside the element body 1 as compared with the imaginary plane PL1d. The plated layer 25 formed on the outer edge 22e is located outside the element body 1 as compared with the imaginary plane PL2e. The plated layer 25 formed on the outer edge 22f is located outside the element body 1 as compared with the imaginary plane PL2f. The plated layer 25 is not formed on the region R3 located in the element body 1. The plated layer 25 is not formed on the edges 21e and 21f.

The external electrodes 10 and 20 include an electrically conductive material. The electrically conductive material includes, for example, Ag, Pd, Au, Pt, Cu, Ni, Al, Mo, Sn, or W. The electrically conductive material includes, for example, an Ag—Pd alloy, an Ag—Cu alloy, an Ag—Au alloy, or an Ag—Pt alloy. The thickness of each of the external electrodes 10 and 20 is, for example, 5 to 20 μm.

The plated layers 15 and 25 include, for example, an Ni plated layer, an Sn plated layer, a Cu plated layer, or an Au plated layer. The electronic component ED1 may include a multilayer structure of these plated layers, and may include a Ni-plated layer and an Au-plated layer formed on the Ni-plated layer. The plated layers 15 and 25 have a thickness of, for example, 1 to 6 μm.

The internal conductor 30 is disposed in the element body 1. In the present example, the internal conductor 30 is disposed in the element body region E2. A portion of the internal conductor 30 is disposed in the element body region E1. The internal conductor 30 includes a coil portion 31 and a through-hole portion 32. The coil portion 31 includes a plurality of coil conductors 31b to 31e. The coil portion 31 has, for example, a spiral shape. In the present example, the axial direction of the coil portion 31 is the third direction D3. The coil conductors 31b to 31e are disposed to at least partially overlap each other when viewed in the third direction D3. The coil conductors 31b to 31e are separated from the principal surfaces 1a and 1b and the side surfaces 1c, 1d, 1e, and 1f.

The through hole portion 32 includes a through hole conductor 33, a through hole conductor 34, and a through hole conductor 35. The through-hole conductor 33 includes a plurality of through-hole conductor layers 33c to 33f. The through-hole conductor 34 includes a through-hole conductor layer 34f. The through-hole conductor 35 includes through-hole conductors 35a to 35e and 35p to 35t. The plurality of coil conductors 31b to 31e are electrically connected to each other through corresponding through-hole conductors 35a to 35d. The plurality of through-hole conductor layers 33c to 33f are electrically connected to each other through corresponding through-hole conductors 35p to 35r.

The through-hole conductor 33 electrically connects the coil portion 31 and the external electrode 10. The through-hole conductor 33 extends in the third direction D3. An end portion of the through-hole conductor 33 close to the principal surface 1b is connected to one end of the internal conductor 30 close to the principal surface 1b. In the present example, an end portion of the through-hole conductor 33 close to the principal surface 1b is connected to one end of the coil conductor 31b. The through-hole conductor 33 electrically connects the coil conductor 31b and the external electrode 10. The through-hole conductor 33 is disposed closer to the side surface 1c than the coil portion 31 when viewed in the third direction D3.

The through-hole conductor 34 electrically connects the coil portion 31 and the external electrode 20. The through-hole conductor 34 extends in the third direction D3. An end portion of the through-hole conductor 34 close to the principal surface 1b is connected to one end of the internal conductor 30 close to the principal surface 1a. In the present example, an end portion of the through-hole conductor 34 close to the principal surface 1b is connected to one end of the coil conductor 31e. The through-hole conductor 34 electrically connects the coil conductor 31e and the external electrode 20. The through-hole conductor 34 is disposed closer to the side surface 1d than the through-hole conductor 33 when viewed in the third direction D3.

The element body 1 includes a plurality of layers 2a to 2f laminated on each other. In the present example, the plurality of layers 2a to 2f are laminated in the third direction D3. The plurality of layers 2a to 2f are laminated to such an extent that mutual boundaries cannot be visually recognized in practice. The layers 2a to 2f include insulator layers 3a to 3f.

The layer 2a includes the insulator layer 3a. The layer 2a includes the outermost layer of the element body 1. The principal surface 2q of the layer 2a includes the principal surface 1b of the element body 1. The layer 2b includes the insulator layer 3b and a coil conductor 31b disposed in the insulator layer 3b. The layer 2c includes the insulator layer 3c, and the coil conductor 31c and the through-hole conductor layer 33c disposed in the insulator layer 3c. The through-hole conductor 35a and the through-hole conductor 35b are disposed between the layer 2b and the layer 2c. The through-hole conductor 35a connects one end of the coil conductor 31b and one end of the coil conductor 31c. The through-hole conductor 35b connects the other end of the coil conductor 31b and the through-hole conductor layer 33c.

The layer 2d includes the insulator layer 3d, and the coil conductor 31d and the through-hole conductor layer 33d disposed in the insulator layer 3d. The through-hole conductor 35c and the through-hole conductor 35p are disposed between the layer 2c and the layer 2d. The through-hole conductor 35c connects the other end of the coil conductor 31c and one end of the coil conductor 31d. The through-hole conductor 35p connects the through-hole conductor layer 33c and the through-hole conductor layer 33d.

The layer 2e includes an insulator layer 3e, and the coil conductor 31e and the through-hole conductor layer 33e disposed in the insulator layer 3e. The through-hole conductor 35d and the through-hole conductor 35q are disposed between the layer 2d and the layer 2e. The through-hole conductor 35d connects the other end of the coil conductor 31d and one end of the coil conductor 31e. The through-hole conductor 35q connects the through-hole conductor layer 33d and the through-hole conductor layer 33e.

The layer 2f includes the insulator layer 3f, and the through-hole conductor layer 33f and the through-hole conductor layer 34f disposed in the insulator layer 3f. The through-hole conductor 35e and the through-hole conductor 35r are disposed between the layer 2e and the layer 2f. The through-hole conductor 35e connects the other end of the coil conductor 31e and the through-hole conductor layer 34f. The through-hole conductor 35r connects the through-hole conductor layer 33e and the through-hole conductor layer 33f. The layer 2f includes the lowermost layer of the element body 1. The principal surface 2q of the layer 2f includes the principal surface 1a of the element body 1. The external electrodes 10 and 20 are disposed in the layer 2f. The portion P1 is located between the external electrode 10 and the external electrode 20 in the first direction D1.

The through-hole conductor 35s is disposed between the layer 2f and the external electrode 10. A through-hole conductor 35t is disposed between the layer 2f and the external electrode 20. The through-hole conductor 35s connects the through-hole conductor layer 33f and the external electrode 10. The through-hole conductor 35t connects the through-hole conductor layer 34f and the external electrode 20. In the present example, the layer 2f may include two layers laminated in the first direction D3. In a configuration in which the layer 2f includes two layers, the through-hole conductor layer is disposed between the two layers. The through hole conductor 35s connects the through hole conductor layer 33f and the external electrode 10 via the through hole conductor layer disposed between the two layers. The through hole conductor 35t connects the through hole conductor layer 34f and the external electrode 20 via the through hole conductor layer disposed between the two layers.

In the element body 1, the electrically insulating material included in each of the insulator layer 3a, the insulator layers 3b to 3e, and the insulator layer 3f is different from each other. In the present example, the insulator layer 3a includes the element body region E1, the insulator layers 3b to 3e include the element body region E2, and the insulator layer 3f includes the element body region E3. The insulator layer 3a includes a first inorganic material. The insulator layers 3b to 3e include a second inorganic material different from the first inorganic material. The insulator layer 3f includes the first inorganic material. In the present example, the first inorganic has hardness larger than the of the second inorganic material. The insulator layer 3a, the insulator layers 3b to 3e, and the insulator layer 3f may include the first inorganic material. The insulator layer 3a, the insulator layers 3b to 3e, and the insulator layer 3f may include the second inorganic material.

The first inorganic material includes, for example, a Ni—Cu—Zn ferrite material, a Ni—Cu—Zn—Mg ferrite material, or a Ni—Cu ferrite material. The first inorganic material includes, for example, a metal oxide. Metallic oxides include, for example, Al₂O₃, SrO, ZrO₂, or TiO₂. The first inorganic material may include an Fe alloy. The first mineral may include a glass-ceramic material or a dielectric material.

The second inorganic material includes, for example, a Ni—Cu—Zn ferrite material, a Ni—Cu—Zn—Mg ferrite material, or a Ni—Cu ferrite material. The second inorganic material may include an Fe alloy. The second mineral may include a glass-ceramic material or a dielectric material.

The inner conductor 30 includes an electrically conductive material. The electrically conductive material includes, for example, Ag, Pd, Au, Pt, Cu, Ni, Al, Mo, or W. The electrically conductive material includes, for example, an Ag—Pd alloy, an Ag—Cu alloy, an Ag—Au alloy, or an Ag—Pt alloy. The internal conductor 30 includes the same electrically conductive material as the external electrodes 10 and 20. The internal conductor 30 may include an electrically conductive material different from that of the external electrodes 10 and 20.

The element body region E1 has hardness larger than the of the element body region E2. The element body region E3 has hardness larger than the of the element body region E2. Hardness of each of the element body regions E1, E2, and E3 is determined by that of the insulator layers 3a to 3f included in the element body regions E1, E2, and E3. Hardness of each of the element body regions E1, E2, and E3 is an indicator indicating the mechanical strength of each of the element body regions E1, E2, and E3.

Hardness of each of the element body regions E1, E2, and E3 is obtained through, for example, a test using a test blade, for example. The test blade includes, for example, stainless steel with a double-sided cutting edge. When hardness of the element body region E1 is obtained through a test using the test blade, the element body 1 is cut in the direction perpendicular to the third direction D3, and a cut surface in the element body region E1 is exposed. The test blade is pressed against the cut surface of the exposed element body region E1 in the third direction D3 to break the element body region E1. In the present example, a force required to break the E1 of the element body region is measured in newtons. When hardness of each of the element body regions E2 and E3 is obtained through the test using the test blade, the cut surfaces in the element body regions E2 and E3 are exposed. According to the same procedure as in the case of the element body region E1, forces required to break the element body regions E2 and E3 are measured. The test blade may include a diamond cone or a steel ball.

In the present example, hardness of each of the element body regions E1, E2, and E3 is obtained from the result of measuring the force required to break the element body regions E1, E2, and E3. The amount of the force required to break is considered to correlate with the amount of hardness. It is assumed that a region where the force necessary for breaking is large has hardness larger than the of a region where the force necessary for breaking is small. When the force required to break the element body region E1 is larger than the force required to break the element body region E2, it is estimated that the element body region E1 has hardness larger than the of the element body region E2. In the present example, the test using the test blade is performed a plurality of times on each of the element body regions E1, E2, and E3. The mean value of a plurality of measurement results is taken as the force required to break the one element body region E1, E2, and E3. The mean value of hardness of the element body regions E1 and E3 is larger than the mean value of hardness of the element body region E2.

Hereinafter, an example of a method for producing the electronic component ED1 will be described. The order of the processes for producing the electronic component ED1 may be changed.

In an example of the making method, first, a slurry and a base material are prepared. The slurry includes a material obtained due to mixing an electrically insulating resin and a solvent. The electrically insulating resin includes, for example, an acrylic resin or a butyral resin. The solvent includes, for example, ethyl carbitol or butyl carbitol. The substrate includes, for example, a PET layer.

Next, the slurry is applied onto a base material due to, for example, a doctor blade method to prepare a plurality of green sheets. The plurality of green sheets coated on the substrate includes first and second green sheets. The element body 1 is formed from first and second green sheets. For example, the insulator layers 3a and 3f are formed from the first green sheet, and the insulator layers 3b to 3e are formed from the second green sheet. The first green sheet forming the insulator layer 3f includes a first surface and a second surface opposed to each other.

The slurry for forming the first green sheet includes the first inorganic material. Preparing the first green sheet includes preparing the first green sheet that includes a first inorganic material. In the present example, preparing the first green sheet includes preparing a first green sheet including particles of the first inorganic material. The slurry for forming the second green sheet includes the second inorganic material. Preparing the second green sheet includes preparing the second green sheet that includes the second inorganic material. In the present example, preparing the second green sheet includes preparing the second green sheet including particles of the second inorganic material.

Through-holes for forming through-hole conductors 35s and 35t are formed in the first green sheet. The through holes are formed, for example, due to irradiating the first green sheet with laser light.

Next, an electrically conductive paste for forming the external electrodes 10, 20 is applied to the first green sheet. In this example, the electrode pattern is formed on the first surface using the electrically conductive paste. The external electrodes 10 and 20 are formed from the electrode pattern. The electrode pattern includes a first portion and a second portion separated from each other. The external electrode 10 is formed from the first portion. The external electrode 20 is formed from the second portion. The electrically conductive paste forming the external electrodes 10 and 20 is prepared due to, for example, mixing a glass component, an alkali metal, an organic binder, and an organic solvent with metal powder including Ag particles or Ag—Pd alloy particles.

Next, an electrically insulating paste for forming an insulating pattern is applied to the first green sheet. The element body 1 is formed from an insulating pattern. In the present example, the insulating pattern is formed using the electrically insulating paste. The insulating pattern is formed between the first portion and the second portion such that the insulating pattern is in contact with the first surface, the first portion, and the second portion. The insulating pattern includes the electrically insulating paste including the first inorganic material. Forming the insulating pattern may include forming the insulating pattern using the electrically insulating paste including the first inorganic material. The electrically insulating paste is applied to the first green sheet through a die coater, for example. The insulating pattern is formed due to drying the electrically insulating paste.

Next, a base is prepared, and the first green sheet is placed on the base. The base includes, for example, a polyethylene-based layer. In this example, the first green sheet on which the electrode pattern and the insulating pattern are formed is placed on the base such that the first portion, the second portion, and the insulating pattern are in contact with the base.

Next, an electrically conductive paste for forming a conductor pattern for forming the through-hole conductor layers 33f and 34f is applied onto the second surface of the first green sheet. Through-hole conductor layers 33f and 34f are formed from the conductor pattern.

The element body 1 is formed from a plurality of second green sheets. The plurality of second green sheets form the insulator layers 3b to 3e. An electrically conductive paste for forming the conductor pattern is applied to the plurality of second green sheets. The conductor pattern forms a plurality of coil conductors 31b to 31e and through-hole conductor layers 33c to 34e. A conductor pattern is formed on the second green sheet using the electrically conductive paste. In the present example, conductor patterns for forming the coil conductors 31b to 31e and the through-hole conductor layers 33c to 34e are formed on the second green sheets. The electrically conductive paste forming the conductor pattern is prepared due to, for example, mixing a glass component, an alkali metal, an organic binder, and an organic solvent with a metal powder including Ag particles or Ag—Pd alloy particles.

The second green sheet of the first layer is disposed on the first green sheet. The second green sheet of the first layer has a conductor pattern that forms the coil conductor 31e and the through-hole conductor layer 33e. Next, the second green sheet of the second layer is laminated. The second green sheet of the second layer has a conductor pattern that forms the coil conductor 31d and the through-hole conductor layer 33d. Next, the second green sheet of the third layer is laminated. The second green sheet of the third layer has a conductor pattern that forms the coil conductor 31c and the through-hole conductor layer 33c. Next, the second green sheet of the fourth layer is laminated. The second green sheet of the fourth layer has a conductor pattern forming the coil conductor 31b. Next, the first green sheet for forming the insulator layer 3a is laminated.

In this example, the green sheet is irradiated with laser light to form through-holes. The through holes formed in the green sheet include through holes that form the through hole conductors 35b to 35e and 35p to 35t.

The second green sheet disposed on the first green sheet may include two sets of second green sheets. Through-holes for forming conductors for electrically connecting the conductor patterns and the electrode patterns are formed in the two sets of second green sheets. The through-holes formed in one of the two sets of second green sheets include through-holes forming through-hole conductors 35e and 35r. The through holes formed in the other of the two sets of second green sheets include through holes forming through-hole conductors 35s and 35t. The through holes formed in the second green sheet are filled with the electrically conductive paste. The electrically conductive paste filled in the through-hole is prepared due to mixing a glass component, an alkali metal, an organic binder, and an organic solvent with a metal powder including Ag particles or Ag—Pd alloy particles.

The laminated first and second green sheets are pressed, for example, in the third direction D3 in which they are laminated. After the laminated first and second green sheets are pressed, a multilayer body in which the conductor patterns forming the coil conductors 31b to 31e overlap each other when viewed in the third direction D3 is formed. In the present example, the multilayer body includes a plurality of portions for forming the element bodies 1. The multilayer body is cut into a predetermined size using, for example, a cutting machine to cut the multilayer body into a plurality of green chips. The plurality of green chips having a predetermined size are obtained. The electronic component ED1 is manufactured due to sintering the green chip. In the present example, the plated layer 15 is formed on the external electrode 10 and the plated layer 25 is formed on the external electrode 20 through a plating method.

The first inorganic material has hardness larger than the of the second inorganic material. Hardness of the first inorganic material is an index indicating the mechanical strength of the particles of the first inorganic material. Hardness of the second inorganic material is an index indicating the mechanical strength of the particles of the second inorganic materials. Hardness of the first and second inorganic materials is determined through, for example, a nanoindentation test.

In the nanoindentation test, a triangular pyramid indenter having a minute size is driven into particles of the first inorganic material included in the slurry for forming the first green sheet. A triangular pyramid indenter having a minute size is also driven into the particles of the second inorganic material included in the slurry for forming the second green sheet. The depth of the tip of the triangular pyramid indenter driven into the particles of the first and second inorganic materials is measured. Hardness of the particles of the first and second inorganic materials is obtained from the measurement results of the depths into which the tip of the triangular pyramid indenter is driven.

In the present example, the nanoindentation test is performed a plurality of times on each of the slurry forming the first green sheet, the electrically conductive paste, and the slurry forming the second green sheet, and the average value of the plurality of measurement results is taken as hardness of the particles of the first and second inorganic materials. The average value of hardness of the particles of the first inorganic material included in the slurry forming the first green sheet is larger than the average value of hardness of the particles of the second inorganic material included in the slurry forming the second green sheet.

As described above, in the electronic component ED1, the edges 11e and 11f and the edges 21e and 21f oppose each other in the second direction D2. The end edges 11e, 11f, 21e, and 21f are located in the element body 1. Therefore, even in a case where the plated layers 15 and 25 are formed on each of the external electrode 10 and the external electrode 20, plating elongation tends not to occur from each of the edges 11e, 11f, 21e, and 21f. The distance between the external electrode 10 and the external electrode 20 tends not to be narrowed. As a result, the electronic component ED1 suppresses a short circuit between the external electrode 10 and the external electrode 20.

The edges 11e and 11f and the edges 21e and 21f are located in the element body 1. Therefore, the electronic component ED1 improves the connection strength between the element body 1 and the external electrodes 10 and 20.

In the electronic component ED1, the entirety of each of the external electrode 10 and the external electrode 20 overlaps with a region when viewed in the third direction D3. The region is defined by the pair of imaginary planes PL1c and PL1d, and the pair of imaginary planes PL2e and PL2f.

In the electronic component ED1, a region where a solder fillet is formed tends not to increase when the electronic component ED1 is solder-mounted on an electronic device. Therefore, the mounting density of the electronic component ED1 on the electronic device can be improved. The electronic device includes, for example, a circuit board or an electronic component.

In the electronic component ED1, each of the region R2 and the region R4 includes outer edges 12c and 22d that overlap with the imaginary planes PL1c and PL1d when viewed in the third direction D3.

In the electronic component ED1, the lengths of the region R2 and the region R4 in the first direction D1 increase. Therefore, the electronic component ED1 can increase the areas of the region R2 and the region R4. As a result, the mounting strength of the electronic component ED1 can be improved.

In the electronic component ED1, the region R2 includes a pair of outer edges 12e and 12f. The outer edge 12e is located on the imaginary plane PL2e when viewed in the third direction D3. The outer edge 12f is located on the imaginary plane PL2f when viewed in the third direction D3. The outer edge 12e overlaps the imaginary plane PL2e when viewed in the third direction D3. The outer edge 12f overlaps the imaginary plane PL2f when viewed in the third direction D3. The region R4 includes a pair of outer edges 22e and 22f. The outer edge 22e is located on the imaginary plane PL2e when viewed in the third direction D3. The outer edge 22f is located on the imaginary plane PL2f when viewed in the third direction D3. The outer edge 22e overlaps the imaginary plane PL2e when viewed in the third direction D3. The outer edge 22f overlaps the imaginary plane PL2f when viewed in the third direction D3.

In the electronic component ED1, the lengths of the region R2 and the region R4 in the second direction D2 increase. Therefore, the electronic component ED1 can increase the areas of the external electrode 10 and the external electrode 20. As a result, the mounting strength of the electronic component ED1 can be improved.

In the electronic component ED1, each of the region R1 and the region R3 is separated from the pair of imaginary planes PL2e and PL2f when viewed in the third direction D3.

In the electronic component ED1, the edges 11e, 11f, 21e, and 21f tend to be reliably positioned in the element body 1. Therefore, the electronic component ED1 reliably suppresses a short circuit between the external electrode 10 and the external electrode 20.

In the electronic component ED1, the distances L1e and L1f are larger than the lengths L1d. The distances L3e and L3f are larger than the length L3c.

In the electronic component ED1, the region R1 is reliably separated from each of the pair of imaginary planes PL2e and PL2f. The region R3 is reliably separated from each of the pair of imaginary planes PL2e and PL2f. Therefore, the end edges 11e, 11f, 21e, and 21f are more reliably positioned in the element body 1. As a result, the electronic component ED1 more reliably suppresses a short circuit between the external electrode 10 and the external electrode 20.

In the electronic component ED1, the ratio of the areas of the regions R1 to the areas of the external electrode 10 and the ratio of the areas of the region R3 to the areas of the external electrode 20 are a range from 0.1 to 0.2.

The electronic component ED1 improves the connection strength between the external electrode 10 and the external electrode 20, and can secure the areas of the region R2 and the region R4. Therefore, the mounting strength of the electronic component ED1 can be ensured.

Although the examples of the present disclosure have been described above, the present disclosure is not necessarily limited to the above-described examples, and various modifications can be made without departing from the scope of the present disclosure.

In the electronic component ED1, the entirety of each of the external electrode 10 and the external electrode 20 may not be located in a region defined by the pair of imaginary planes PL1c and PL1d and the pair of imaginary planes PL2e and PL2f when viewed in the third direction D3. In the configuration in which the entirety of each of the external electrode 10 and the external electrode 20 is located in the region defined by the imaginary planes PL1c and PL1d and the imaginary planes PL2e and PL2f, as described above, when the electronic component ED1 is solder-mounted on the electronic device, the region where the solder fillet is formed tends not to increase. Therefore, the mounting density of the electronic component ED1 on the electronic device can be improved.

In the present example, the electronic component ED1 is described as a multilayer inductor, but the electronic component to which the present disclosure can be applied is not limited to the multilayer inductor. Applicable electronic components include, for example, multilayer ceramic capacitors, multilayer varistors, multilayer piezoelectric actuators, multilayer thermistors, and multilayer solid state batteries.

What is claimed is:

1. An electronic component comprising:
an element body including a principal surface, a pair of first side surfaces opposing each other in a first direction and adjacent to the principal surface, and a pair of second side surfaces opposing each other in a second direction intersecting with the first direction and adjacent to the principal surface; and
a first external electrode and a second external electrode disposed on the principal surface and separated from each other in the first direction,
wherein the first external electrode includes:
a first region including an end edge opposing the second external electrode in the first direction and located inside the element body, and
a second region being continuous with the first region and being exposed from the principal surface, and
the second external electrode includes:
a third region including an end edge opposing the first region in the first direction and located inside the element body, and
a fourth region being continuous with the third region and being exposed from the principal surface.

2. The electronic component according to claim 1, wherein
each of the first external electrode and the second external electrode entirely overlaps an imaginary region when viewed in a direction orthogonal to the principal surface, the imaginary region being defined by a pair of first imaginary planes each including a corresponding first side surface of the pair of first side surfaces and a pair of second imaginary planes each including a corresponding second side surface the pair of second side surfaces.

3. The electronic component according to claim 1, wherein
each of the second region and the fourth region includes an outer edge overlapping a corresponding imaginary plane of a pair of imaginary planes when viewed in a direction orthogonal to the principal surface, the pair of imaginary planes each including a corresponding first side surface of the pair of first side surfaces.

4. The electronic component according to claim 1, wherein
each of the second region and the fourth region includes a pair of outer edges each overlapping a corresponding imaginary plane of a pair of imaginary planes when viewed in a direction orthogonal to the principal surface, the pair of imaginary planes each including a corresponding second side surface of the pair of second side surfaces.

5. The electronic component according to claim 1, wherein
each of the first region and the third region is separated from a pair of imaginary planes when viewed in a direction orthogonal to the principal surface, the pair of imaginary planes each including a corresponding second side surface of the pair of second side surfaces.

6. The electronic component according to claim 5, wherein
a distance in the second direction between each of the pair of second imaginary planes and the first region is larger than a length of the first region in the first direction, and
a distance in the second direction between each of the pair of second imaginary planes and the third region is larger than a length of the third region in the first direction.

7. The electronic component according to claim 1, wherein
a ratio of an area of the first region to an area of the first external electrode and a ratio of an area of the third region to an area of the second external electrode are a range from 0.1 to 0.2.
